(19) United States
(12) Patent Application Publication
(10) Pub. No.: US 2022/0157978 A1
(43) Pub. Date: May 19, 2022

(54) p-GaN HIGH ELECTRON MOBILITY TRANSISTOR

(71) Applicant: NATIONAL SUN YAT-SEN UNIVERSITY, Kaohsiung (TW)

(72) Inventors: Ting-Chang Chang, Kaohsiung (TW); Hong-Chih Chen, Kaohsiung (TW); Hao-Xuan Zheng, Kaohsiung (TW); Yu-Shan Lin, Kaohsiung (TW); Fu-Yuan Jin, Kaohsiung (TW); Fong-Min Ciou, Kaohsiung (TW); Yun-Hsuan Lin, Kaohsiung (TW); Mao-Chou Tai, Kaohsiung (TW); Wen-Chung Chen, Kaohsiung (TW)

(21) Appl. No.: 17/105,550

(22) Filed: Nov. 26, 2020

(30) Foreign Application Priority Data
Nov. 13, 2020 (TW) 109139759

(51) Int. Cl. H01L 29/778; H01L 29/20

(52) U.S. Cl. CPC H01L 29/7786; H01L 29/2003

(57) ABSTRACT

A p-GaN high electron mobility transistor is disclosed. The p-GaN high electron mobility transistor includes a substrate, a channel layer located on the substrate, a supply layer laminated on the channel layer, and a doped layer laminated on the supply layer. A doping concentration of the doped layer is gradually distributed, in which the doping concentration in a first doped region close to the supply layer is lower than a doping concentration in a second doped region distant from the supply layer. A gate electrode is located on the doped layer. A source electrode and a drain electrode are respectively electrically connected to the channel layer and the supply layer.

### CROSS REFERENCE TO RELATED APPLICATION

The application claims the benefit of Taiwan application serial No. 109139759, filed on Nov. 13, 2020, and the entire contents of which are incorporated herein by reference.

### BACKGROUND OF THE INVENTION

### 1. Field of the Invention

The present invention generally relates to an electronic component and, more particularly, to a p-GaN high electron mobility transistor capable of reducing the tunneling current to improve the component reliability.

### 2. Description of the Related Art

Gallium nitride (GaN) has physical characteristics such as high breakdown voltage, high electron saturation rate, and better thermal stability, thus becoming one of the most popular semiconductor materials recently. However, when the gate electrode is not provided with bias, the conventional GaN high electron mobility transistors are still in conducting states, resulting in safety concern. Therefore, the common GaN high electron mobility transistor nowadays utilizes a p-type GaN gate structure to realize an enhanced mode gate driving switch, as shown in FIG. 1, which shows a conventional p-type GaN high electron mobility transistor. The conventional p-type GaN high electron mobility transistor 9 includes a channel layer 12, a supply layer 13, an enhancement layer 14, and a passivation layer 15 laminated in sequence, and further includes a gate electrode G, a source electrode S, and a drain electrode D. The gate electrode G is located on the enhanced layer 14. The source electrode S and the drain electrode D are electrically connected to the channel layer 12 and the supply layer 13, respectively. As such, an extremely thin depletion region is formed between the supply layer 13 and the enhanced layer 14, resulting in direct tunneling of the carriers E. Therefore, more leakage current of the gate electrode G is induced so that the reliability of the conventional p-type GaN high electron mobility transistor 9 is decreased. In addition, the on-state current of the transistor 9 drops after long operation time because of the electron trapping phenomenon by the defects of the interface between the supply layer 13 and the passivation layer 15.

In light of the above problem, it is necessary to improve the conventional p-GaN high electron mobility transistor.

### SUMMARY OF THE INVENTION

It is therefore an objective of the present invention to provide a p-GaN high electron mobility transistor which can reduce the tunneling current and improve the reliability.

It is another objective of the present invention to provide a p-GaN high electron mobility transistor which can reduce the technical difficulty and cost of production.

It is yet another objective of the present invention to provide a p-GaN high electron mobility transistor which can improve the on-state current drop phenomenon after continuous operation of the transistor.

As used herein, the term “a”, “an”, or “one” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

A p-GaN high electron mobility transistor according to a first embodiment includes a substrate, a channel layer located on the substrate, a supply layer laminated on the channel layer, and a doped layer laminated on the supply layer. A doping concentration of the doped layer is gradually distributed, in which the doping concentration in a first doped region close to the supply layer is lower than a doping concentration in a second doped region distant from the supply layer. A gate electrode is located on the doped layer. A source electrode and a drain electrode are respectively electrically connected to the channel layer and the supply layer.

Accordingly, the p-GaN high electron mobility transistor according to the first embodiment utilizes gradually distributed doping concentration to improve the electrical characteristics of the transistor, which can enlarge the depletion region to reduce the occurrence of tunneling current, thereby improving the leakage phenomenon and enhancing the performance and reliability of the transistor. Since there is no need to modify the transistor structure, it does not require additional photomask during the manufacturing process, achieving the effects of reducing the technical difficulty and cost for production.

In an example, the doping concentration in the first doped region is between 1×10¹⁶ and 1×10¹⁸ atom/cm³. As such, utilizing low doping concentration can increase the width of the depletion region between the doped layer and the supply layer, which can effectively suppress the tunneling current caused by a big electric field.

In an example, the doped layer is a p-type doped layer doped with IIA elements. As such, the P-type doped layer can improve the leakage phenomenon of the transistor, ensuring the effects of enhancing the performance and reliability of the transistor.

In an example, the p-GaN high electron mobility transistor further includes a buffer layer located on the substrate, and a barrier layer located between the buffer layer and the channel layer. As such, the buffer layer can reduce the adverse effect of the hetero structure between the substrate and the channel layer on the epitaxial process, and the barrier layer can prevent a large amount of electrons from entering the buffer layer, ensuring the effect of enhancing the reliability of the transistor.

In an example, the p-GaN high electron mobility transistor further includes a passivation layer laminated on the supply layer, the gate electrode, the source electrode, and the drain electrode. As such, the passivation layer can protect the electrical characteristics of the underlying layers and electrodes from being affected by the environment, ensuring the effect of enhancing the reliability of the transistor.

A p-GaN high electron mobility transistor according to a second embodiment includes a substrate, a channel layer located on the substrate, a supply layer laminated on the channel layer, a first doped layer laminated on the supply layer, and a second doped layer laminated on the first doped layer. A doping concentration in the first doped layer is lower than a doping concentration in the second doped layer. A gate electrode is located on the second doped layer. A source electrode and a drain electrode are respectively electrically connected to the channel layer and the supply layer.

Accordingly, the p-GaN high electron mobility transistor according to the second embodiment utilizes double-layer doping concentration to improve the electrical characteristics of the transistor, which can enlarge the depletion region to reduce the occurrence of tunneling current, thereby improving the leakage phenomenon and enhancing the performance and reliability of the transistor. Since there is no need to modify the transistor structure, it does not require additional photomask during the manufacturing process, achieving the effects of reducing the technical difficulty and cost for production.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is a stack cross-sectional view according to a conventional p-type GaN high electron mobility transistor.

FIG. 2 is a stack cross-sectional view according to a first embodiment of the present invention.

FIG. 3 is an electric field distribution diagram along line Source-Drain shown in FIG. 2.

FIG. 4 is a stack cross-sectional view according to a second embodiment of the present invention.

In the various figures of the drawings, the same numerals designate the same or similar parts. Furthermore, when the terms “left”, “right”, “up (top)”, “low (bottom)”, and similar terms are used herein, it should be understood that these terms have reference only to the structure shown in the drawings as it would appear to a person viewing the drawings and are utilized only to facilitate describing the invention, rather than restricting the invention.

### DETAILED DESCRIPTION OF THE INVENTION

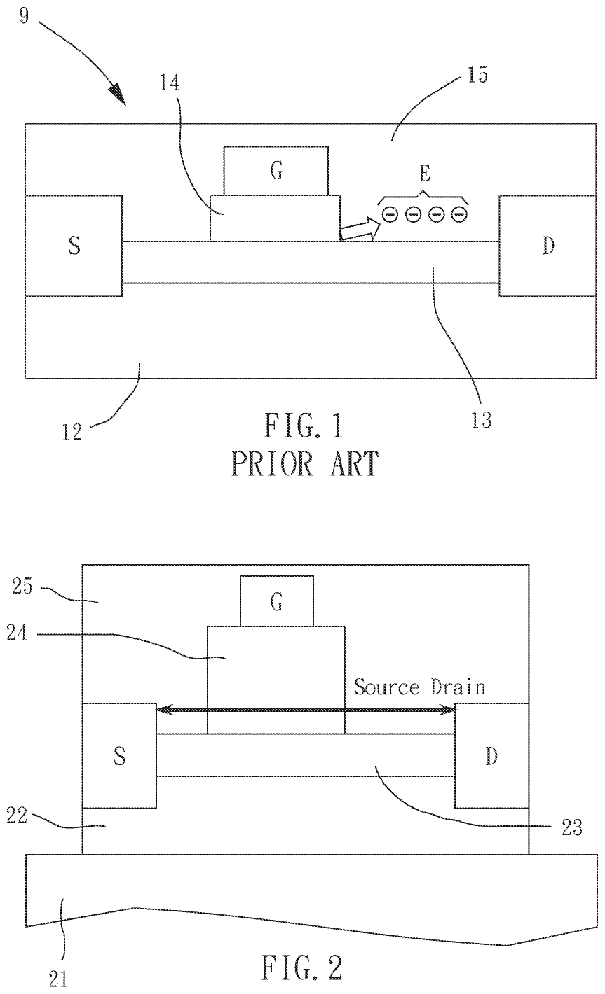

Referring to FIG. 2, the p-GaN high electron mobility transistor according to a first embodiment of the present invention includes a substrate 21, a channel layer 22, a supply layer 23, and a doped layer 24. The channel layer 22 is located on the substrate 21. The supply layer 23 is laminated on the channel layer 22. The doped layer 24 is laminated on the supply layer 23.

The substrate 21 carries transistors. The loss of electrons can be reduced and harmful electrical effects can be prevented by having transistor materials such as metal, insulators and semiconductors formed on the substrate 21. The material of the substrate 21 is preferably silicon.

The channel layer 22 and the supply layer 23 respectively have materials with energy gaps different from each other. A two-dimensional electron gas (2DEG) is formed at the hetero structure interface between the channel layer 22 and the supply layer 23. Therefore, a channel for rapid electrons migration is provided to render the transistor good characteristics of high frequency operation. In this embodiment, the channel layer 22 includes gallium nitride, and the supply layer 23 includes gallium aluminum nitride. As such, a two-dimensional electron gas can be formed at the hetero structure interface between the supply layer 23 and the channel layer 22 to provide as a channel for electrons to move quickly, ensuring the effect of improving the high frequency operation of the transistor.

A doping concentration of the doped layer 24 is gradually distributed. For example, the thickness of the doped layer 24 is 50 nanometers, and the doping concentration gradually increases from bottom to top along the stacking direction. More specifically, the doping concentration in a first doped region close to the supply layer 23 is lower than the doping concentration in a second doped region distant from the supply layer 23. That is, the doped layer 24 has a gradually distributed doping concentration, which can increase the width of the depletion region between the doped layer 24 and the supply layer 23, thereby reducing the occurrence of tunneling current.

The p-type GaN high electron mobility transistor further has a gate electrode G, a source electrode S, and a drain electrode D. The gate electrode G is located on the doped layer 24. The source electrode S and the drain electrode D are respectively electrically connected to the channel layer 22 and the supply layer 23. Therefore, the electrons between the source electrode S and the drain electrode D can efficiently migrate between the channel layer 22 and the supply layer 23. Furthermore, the output current of the drain electrode D can be adjusted by the electric field provided between the gate electrode G and the substrate 21.

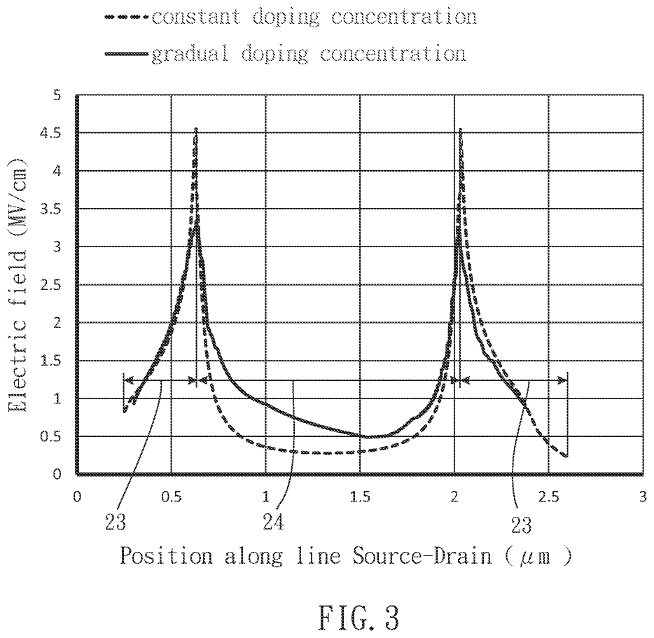

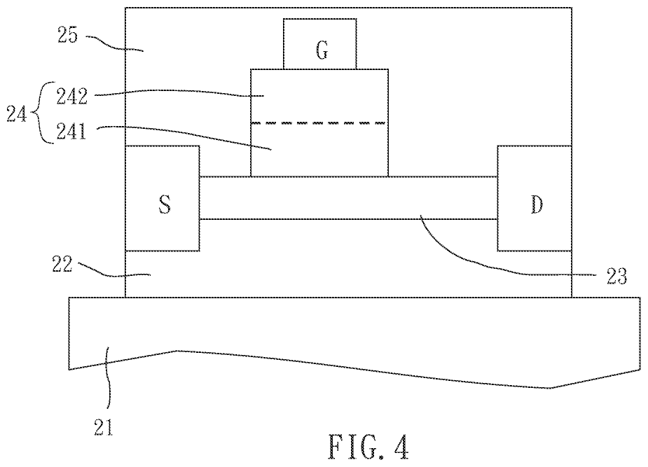

Referring to FIG. 1 and FIG. 2 together, compared with the conventional laminated structure in which the enhanced layer 14 has a constant doping concentration of about 1×10¹⁹ atom/cm³, the p-type GaN high electron mobility transistor according to the first embodiment has a lower doping concentration of the doped layer 24 in a region close to the supply layer 23, thereby the doping concentration of the doped layer 24 is gradually distributed. Please refer to FIG. 3, which shows the electric field distribution diagram of the two types of laminated structures as described above during operation. The electric field change diagram is shown by marking the electric fields in sequence from the supply layer 23, the doped layer 24, until the supply layer 23, corresponding to each position along line Source-Drain shown in FIG. 2. The intensity value of the electric field at the interface of the supply layer 23 and the doped layer 24 is greatly reduced to about 3.3 MV/cm, and a thickened depletion region is formed therebetween. Thus, direct tunneling of electrons is not easy to occur, so that the gate electrode G leakage current is reduced, and the effect of improving the reliability of the transistor is achieved.

According to the structure as mentioned above, the p-GaN high electron mobility transistor according to the first embodiment utilizes gradually distributed doping concentration to improve the electrical characteristics of the transistor, which can enlarge the depletion region to reduce the occurrence of tunneling current, thereby improving the leakage phenomenon and enhancing the performance and reliability of the transistor. Since there is no need to modify the transistor structure, it does not require additional photomask during the manufacturing process, achieving the effects of reducing the technical difficulty and cost for production.

In some embodiments, the doping concentration in the first doped region is between 1×10¹⁶ and 1×10¹⁸ atom/cm³. As such, controlling the doping concentration at a low value can increase the width of the depletion region between the doped layer 24 and the supply layer 23, which can effectively suppress the tunneling current caused by an electric field.

In some embodiment, the doped layer 24 is a p-type doped layer doped with IIA elements. As such, the P-type doped layer can improve the transistor leakage phenomenon, ensuring the effects of enhancing the performance and reliability.

In some embodiments, the p-GaN high electron mobility transistor further includes a buffer layer and a barrier layer (not shown). The buffer layer is located on the substrate 21, and the barrier layer is located between the buffer layer and the channel layer 22. The barrier layer is preferably undoped aluminum gallium nitride so that no additional photomask is required during the manufacturing process. As such, the buffer layer can reduce the adverse effect of the heterostructure between the substrate 21 and the channel layer 22 on the epitaxial process, so as to improve the crystal quality and electronic characteristics of the transistor. Furthermore, the barrier layer can prevent a large amount of electrons from entering the buffer layer, which can reduce the kink effect. In addition, in the process of manufacturing the p-type GaN high electron mobility transistor, the buffer layer is formed first, and then the barrier layer is formed in another layer. Thus, there is no need for additional photomask and complicated processes, ensuring the effects of reducing production costs and enhancing performance of the transistor.

In some embodiments, the p-GaN high electron mobility transistor further includes a passivation layer 25, which is laminated on the supply layer 23, the gate electrode G, the source electrode S, and the drain electrode D. As such, the passivation layer 25 can protect the electrical characteristics of the underlying layers and electrodes from being affected by the environment, ensuring the effect of improving the reliability of the transistor. For example, the material of the passivation layer 25 is silicon nitride (SiN), silicon dioxide (SiO₂), or aluminum oxide (Al₂O₃), etc., and has the characteristics such as thermal shock resistance and electrical insulation.

Referring to FIG. 4, the p-type GaN high electron mobility transistor according to a second embodiment of the present invention includes a substrate 21, a channel layer 22, a supply layer 23, a first doped layer 241, and a second doped layer 242. The channel layer 22 is located on the substrate 21. The supply layer 23 is laminated on the channel layer 22. The first doped layer 241 is laminated on the supply layer 23, and the second doped layer 242 is laminated on the first doped layer 241. The second embodiment differs from the first embodiment in that it changes the doping concentration in double-layer form. For example, the first doped layer 241 is a lightly doped p-type GaN layer (p-GaN) with a thickness of 25 nm, while the second doped layer 242 is a heavily doped p-type GaN layer (p⁺-GaN) with a thickness of 25 nm. Accordingly, by utilizing double-layer doping concentration to improve the electrical characteristics of the transistor, those functions, effects, advantages, and derivative embodiments of the first embodiment as mentioned above can also be realized, which are therefore omitted. The structural features of the components, connection relationships between the components, effects, advantages, and derivative embodiments of the substrate 21, the channel layer 22, and the supply layer 23 are as described above.

Based on the above, the p-GaN high electron mobility transistor according to some embodiments utilizes gradually/double-layer doping concentration to improve the electrical characteristics of the transistor, which can enlarge the depletion region to reduce the occurrence of tunneling current, thereby improving the leakage phenomenon and enhancing the performance and reliability of the transistor. Since there is no need to modify the transistor structure, it does not require additional photomask during the manufacturing process, achieving the effects of reducing the technical difficulty and cost for production. In addition, the source of electrons trapped by the defects of the interface between the supply layer and the passivation layer can be reduced, which can improve the on-state current drop phenomenon after continuous operation of the transistor.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A p-GaN high electron mobility transistor comprising:
a substrate;
a channel layer located on the substrate;
a supply layer laminated on the channel layer; and
a doped layer laminated on the supply layer, wherein a doping concentration of the doped layer is gradually distributed, and the doping concentration in a first doped region close to the supply layer is lower than a doping concentration in a second doped region distant from the supply layer, wherein a gate electrode is located on the doped layer, and a source electrode and a drain electrode are respectively electrically connected to the channel layer and the supply layer.

2. The p-GaN high electron mobility transistor as claimed in claim 1, wherein the doping concentration in the first doped region is between 1×10¹⁶ and 1×10¹⁸ atom/cm³.

3. The p-GaN high electron mobility transistor as claimed in claim 1, wherein the doped layer is a p-type doped layer doped with IIA elements.

4. The p-GaN high electron mobility transistor as claimed in claim 1, further comprising:
a buffer layer located on the substrate; and
a barrier layer located between the buffer layer and the channel layer.

5. The p-GaN high electron mobility transistor as claimed in claim 1, further comprising a passivation layer laminated on the supply layer, the gate electrode, the source electrode, and the drain electrode.

6. The p-GaN high electron mobility transistor as claimed in claim 2, further comprising a passivation layer laminated on the supply layer, the gate electrode, the source electrode, and the drain electrode.

7. The p-GaN high electron mobility transistor as claimed in claim 3, further comprising a passivation layer laminated on the supply layer, the gate electrode, the source electrode, and the drain electrode.

8. The p-GaN high electron mobility transistor as claimed in claim 4, further comprising a passivation layer laminated on the supply layer, the gate electrode, the source electrode, and the drain electrode.

9. A p-GaN high electron mobility transistor comprising:
a substrate;
a channel layer located on the substrate;
a supply layer laminated on the channel layer;
a first doped layer laminated on the supply layer; and
a second doped layer laminated on the first doped layer, wherein a doping concentration in the first doped layer is lower than a doping concentration in the second doped layer, wherein a gate electrode is located on the second doped layer, and a source electrode and a drain electrode are respectively electrically connected to the channel layer and the supply layer.

10. The p-GaN high electron mobility transistor as claimed in claim 9, wherein the doping concentration in the first doped layer is between 1×10¹⁶ and 1×10¹⁸ atom/cm³.

11. The p-GaN high electron mobility transistor as claimed in claim 9, wherein the first doped layer is a p-type doped layer doped with IIA elements.

12. The p-GaN high electron mobility transistor as claimed in claim 9, further comprising:
a buffer layer located on the substrate; and
a barrier layer located between the buffer layer and the channel layer.

13. The p-GaN high electron mobility transistor as claimed in claim 9, further comprising a passivation layer laminated on the supply layer, the gate electrode, the source electrode, and the drain electrode.

14. The p-GaN high electron mobility transistor as claimed in claim 10, further comprising a passivation layer laminated on the supply layer, the gate electrode, the source electrode, and the drain electrode.

15. The p-GaN high electron mobility transistor as claimed in claim 11, further comprising a passivation layer laminated on the supply layer, the gate electrode, the source electrode, and the drain electrode.

16. The p-GaN high electron mobility transistor as claimed in claim 12, further comprising a passivation layer laminated on the supply layer, the gate electrode, the source electrode, and the drain electrode.
